(19) United States
(12) Patent Application Publication
(10) Pub. No.: US 2009/0142164 A1
(43) Pub. Date: Jun. 4, 2009

(54) CONTAINER LID OPENING/CLOSING SYSTEM AND SUBSTRATE PROCESSING METHOD USING THE SYSTEM

(75) Inventors: Toshihiko MIYAJIMA, Tokyo (JP); Hiroshi Igarashi, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK CORPORATION, Tokyo (JP)

(21) Appl. No.: 12/276,651

(22) Filed: Nov. 24, 2008

(30) Foreign Application Priority Data
Nov. 29, 2007 (JP) 2007-308927

(51) Int. Cl. H01L 21/67; H01L 21/677

(52) U.S. Cl. 414/217; 414/805

(57) ABSTRACT

An FIMS system in which loading is possible in a manner in which multiple thin pods are vertically stacked together, in which attraction pads are arranged on plates on which the pods are loaded, the pods being retained by and fixed to the plates through attraction and retention by the pads. A tube for imparting an attraction force to the attraction pads is accommodated in an accommodation space inside box-like member of a minimum requisite space thickness, and the region where the tube can be reflected only exists within the accommodation space.

### BACKGROUND OF THE INVENTION

1. Field of the Invention

The present invention relates to a form of a so-called Front-Opening Interface Mechanical Standard (FIMS) system that is used when transferring, in a semiconductor manufacturing process or the like, reticles, wafers or the like contained in conveying containers called pods between semiconductor processing apparatuses or the like. More specifically, the present invention relates to an FIMS system, that is, a lid opening/closing system, which simultaneously deals with multiple pods called Front-Opening Unified Pods (FOUP), i.e., thin sealed containers each accommodating several reticles or the like, and which opens and closes the lids of the pods to effect transfer of reticles or the like with respect to the pods, and to a substrate processing method using the system.

2. Related Background Art

Up to now, a semiconductor manufacturing process has been conducted in a so-called clean room in which semiconductor wafers are treated with high cleanliness maintained therein. However, in order to cope with an increase in wafer size and reduce a cost required for maintenance of the clean room, a method of maintaining only the inside of a processing apparatus, the pod (container of wafer to be contained), and a mini-environment for substrate transfer from the pod to the processing apparatus in a highly clean state is employed in recent years.

The pod includes a substantially-cube-shaped main body having a rack capable of retaining multiple wafers therein in a state where the wafers are separated from one another in parallel and having an opening which is used for putting in/taking out wafers on one of the surfaces constituting an outer surface, and a lid which closes the opening. A pod in which a surface on which the opening is formed is located not vertically below the pod but on a side surface of the pod (in front of the mini-environment) is generically called a front-opening unified pod (FOUP). The present invention is mainly intended for a structure using the FOUP. Conventionally, from the viewpoint of production efficiency, etc., there have been used pods each accommodating ten or more wafers. Nowadays, however, due to an increase in wafer diameter, an increase in the requisite number of processes for each wafer, etc., it has come to be considered more preferable to adopt a method in which several wafers are accommodated in each pod and in which the wafers are supplied to individual apparatuses in smaller lots. Japanese Patent Application Laid-Open No. 2004-262654 discloses in detail such a thin pod dedicated to accommodate several wafers and the handling of the same.

The above-mentioned mini-environment includes a pod side opening opposed to the opening of the pod, a door for closing the pod side opening, an opening provided on a semiconductor processing apparatus side, and a transfer robot that moves from the pod side opening to the inside of the pod to retain the wafer and passes through the opening on a semiconductor processing apparatus side to transfer the wafer to the semiconductor processing apparatus side. A structure for forming the mini-environment includes a mount base for supporting the pod so that the opening of the pod is simultaneously opposed to the front surface of the door. The mount base is normally movable back and forth with respect to a door direction by a predetermined distance. When the wafers in the pod are to be transferred to the processing apparatus, the pod is moved in a state where the pod is mounted until the lid of the pod comes in contact with the door. After that contact, the lid is removed from the opening of the pod by the door. With the operations described above, the inside of the pod is connected to the inside of the processing apparatus through the mini-environment. Subsequently, wafer transfer operation is repeated. A system including the mount base, the door, the pod side opening, a door opening/closing mechanism, a wall which is a part of the mini-environment including the pod side opening, and the like is generally called a front-opening interface mechanical standard (FIMS) system.

As stated above, conventionally, a construction intended for the handling of a single pod accommodating ten or more wafers has been sufficient. However, in the case of a thin pod as described above, from the viewpoint of reducing the processing time, it is necessary to enable to perform supply of wafers or the like to the mini-environment through substantially simultaneous use of multiple pods or overlapping the periods during which they are in the mounted state. Further, such handling of wafers can also be applied to conveyance of reticles or the like used in exposure processing or the like. Here, in the case in which thin multiple pods are to be dealt with, a construction may be adopted in which, from the viewpoint of minimizing the grounding area, multiple pods are vertically stacked together. Japanese Patent Application Laid-Open No. 2000-286319 discloses an apparatus serving as a lid opening/closing system corresponding to such pod arrangement. In this construction, multiple pod side openings as described above are formed vertically, and the doors closing the openings are rotated around an axis extending in the longitudinal direction of the rectangular openings, thereby minimizing the space occupied by the requisite mechanism for opening/closing the doors.

In some cases, when placing, that is, loading the pod with respect to the lid opening/closing mechanism, the sealing surfaces, for example, of the pod and the lid are brought into intimate contact with each other in the lid opening/closing operation, whereby an excessive load is applied to the pod for separating the pod and the lid. In such cases, if the pod is not fixed to the lid opening/closing mechanism, the pod may undergo positional deviation, making it impossible to perform normal lid opening/closing operation. In view of this, the pod is usually fixed to the lid opening/closing mechanism by some device. According to Japanese Patent Laid-Open No. 2004-262654, conveyance is conducted with the pod being suspended from above. By using a mechanism for the suspension, it is possible to fix in position a pod with a certain degree of load. However, the load is basically based on the weight of the pod, and when a load of a certain degree or more is applied, or, further, when a force in a specific direction is applied, there is the possibility of positional deviation being easily generated.

Here, as a clamp mechanism for FOUP leading to the system, there is known, for example, a construction disclosed in Japanese Patent Laid-Open No. 2002-164412. In the construction, it is always possible to clamp and retain a pod with a certain degree or more of load. However, in the case of an ultra-thin FOUP lid opening/closing system to which the present invention is to be applied, the distance between the plate on which a pod is placed and another pod arranged below the plate is very small, and it may be difficult to arrange a conventional clamp mechanism. Further, it will also be actually impossible to add a clamp mechanism to the construction disclosed in Japanese Patent Laid-Open No. 2004-262654 in an attempt to retain the pod with a certain degree of strength due to the restriction in terms of space, and further, due to the restriction of securing a space for pod loading operation by a conveyance robot.

### SUMMARY OF THE INVENTION

The present invention has been made in view of the above-mentioned problems in the prior art. It is an object of the present invention to provide a lid opening/closing system in which multiple thin pods are vertically arranged side by side for their processing, in which the pods can be fixed in position with respect to the lid opening/closing system with a certain degree of load, and a substrate processing method for performing various processings on wafers by using the system.

In order to solve the above-mentioned problem, the present invention provides a lid opening/closing system having a container provided with a substantially box-like main body capable of accommodating in an interior thereof an object to be accommodated and having an opening in one surface extending in a vertical direction and a lid separable from the main body and adapted to close the opening to form a sealed space together with the main body, the opening being opened by removing the lid from the container to thereby allow insertion/extraction of the object to be accommodated, the lid opening/closing system including: a container support mechanism supporting the container and capable of moving the container in a predetermined direction; a mini-environment separated from an external space except for an opening of a predetermined size, dust-controlled, and accommodating a mechanism conveying the object to be accommodated; a door having a retaining mechanism abutting the lid and retaining the lid and adapted to rotate around a rotation shaft orthogonal to the predetermined direction and parallel to an extension surface of the object to be accommodated to thereby substantially close or establish communication between the interior of the container and the mini-environment; and an attracting means arranged on an upper surface of the container support mechanism and capable of attracting and retaining a bottom surface of the container.

Note that, it is preferable for the lid opening/closing system to further include a tunnel having an external space side opening that is an opening on the external space side in the vicinity of a position where the container is loaded in the container support mechanism, and a mini-environment side opening communicating with the mini-environment, opening on the mini-environment side, and matched with the opening of the predetermined size, in which the position where the attracting means attracts and retains the container is a position where the attracting means does not enter the tunnel even when the container support mechanism has conveyed the container to a position closest to the mini-environment. Further, it is preferable that the attracting means have an attraction pad actually attracting and retaining the container and a tube-like member connecting the attraction pad to an exhaust system for supplying an attraction force to the attraction pad, and the lid opening/closing system further include a box-like member for accommodating in a substantially closed space a region of the tube-like member that deflects as the container support mechanism operates. Further, in this case, it is particularly preferable that a member directly supporting the container in the container support mechanism be a flat-plate-like member, and the box-like member be arranged on a back surface of the flat-plate-like member and fixed to the lid opening/closing system independently of the container support mechanism.

In order to solve the above-mentioned problem, the present invention provides a lid opening/closing system having a container provided with a substantially box-like main body capable of accommodating an object to be accommodated in an interior thereof and having an opening in one surface extending in a vertical direction and a lid separable from the main body and adapted to close the opening to form a sealed space together with the main body, the opening being opened by removing the lid from the container to thereby allow insertion/extraction of the object to be accommodated, the lid opening/closing system including: a container support mechanism supporting the container and capable of moving the container in a predetermined direction; a mini-environment separated from an external space, dust-controlled, and accommodating a mechanism conveying the object to be accommodated; a tunnel having an external space side opening that is an opening on the external space side in the vicinity of a position where the container is loaded in the container support mechanism, and a mini-environment side opening communicating with the mini-environment and opening on the mini-environment side; a door having a retaining mechanism abutting the lid and retaining the lid and adapted to rotate around a rotation shaft orthogonal to the predetermined direction and parallel to an extension surface of the object to be accommodated and capable of canceling a state in which the tunnel is substantially closed; and an attracting means arranged on an upper surface of the container support mechanism and capable of attracting and retaining a bottom surface of the container, in which the position where the attracting means attracts and retains the container is a position where the container does not enter the tunnel even when the container support mechanism has conveyed the container to a position closest to the mini-environment.

Further, in order to solve the above-mentioned problem, there is provided a method of processing an object to be accommodated which uses a container provided with a substantially box-like main body capable of accommodating an object to be accommodated in an interior thereof and having an opening in one surface extending in a vertical direction and a lid separable from the main body and adapted to close the opening to form a sealed space together with the main body, the opening being opened by removing the lid from the container to thereby allow insertion/extraction of the object to be accommodated, the object to be accommodated being inserted/extracted into/from the container, a predetermined processing being performed on the object to be accommodated outside the container, the method of processing an object to be accommodated using a lid opening/closing system including: a mini-environment that is dust-controlled; a conveyance mechanism for the object to be accommodated arranged inside the mini-environment; a door substantially closing an opening provided in the mini-environment and capable of retaining the lid; and a support mechanism supporting the container to drive the container in a predetermined direction and causing the door to retain the lid, the method of processing an object to be accommodated including: fixing the container with respect to the support mechanism, with the container being supported by the support mechanism; driving the support mechanism to cause the lid to abut the door to thereby cause the door to retain the lid; driving the support mechanism and the door relative to each other in the predetermined direction to separate the container and the lid from each other; rotating the lid and the door around a shaft orthogonal to the predetermined direction and contained in an extension surface of the object to be accommodated to cause the lid and the door to retreat from the drive region of the container; driving the container in the predetermined direction to arrange the container at an insertion/extraction position for the object to be accommodated, in which the operation accompanying the opening/driving of the lid of the container is executed in a tunnel communicating with the mini-environment, and in which the container is fixed in position by being attracted and retained by an attracting means provided in the support mechanism, with a position where the attracting means attracts and retains the container being situated outside the tunnel when the container is arranged at the insertion/extraction position for the object to be accommodated.

According to the present invention, even in the case of a lid opening/closing system for thin FOUP with no vertical space, it is possible to suitably fix and retain the FOUP, that is, the pod, with respect to the system. Further, according to the present invention, the pod is fixed in position through attraction and retention, and hence it is possible to completely prevent dust generation from the clamp mechanism, which has conventionally occurred in the clamp and constituted a problem in performing processing on the pods vertically stacked together. Further, in the case of a lid opening/closing mechanism having a so-called tunnel which helps to execute the present invention still more effectively and which has been proposed by the present applicant, the attraction pad is arranged at a position where it is always outside the tunnel, whereby it is also possible to attain the effect of preventing dust or the like being sucked by the attraction pad into the space intended to maintain cleanliness.

Further, in the present invention, the member constituting the route from the attraction pad to the so-called exhaust system and forming the portion of the lid opening/closing system in the vicinity of the attraction pad is formed as a tube-shaped member of a so-called flexible material such a vinyl. Thus, when a space of a thickness corresponding to the outer diameter of the tube can be secured, it is possible to move without restriction in movement the plate on which the pod is placed. Further, by adding the tube cover of this embodiment, it is possible to prevent dust or the like generated through sliding of the tube at the time of movement of the plate from reaching a component such as the pod arranged below the plate. Further, at the time of sliding of the tube, dust or the like is prevented from being downwardly deflected to come into contact with the pod or the like situated below, thus minimizing the requisite space for arranging the tube.

The above and other objects, features, and advantages of the invention will become more apparent from the following detailed description taken in conjunction with the accompanied drawings.

### BRIEF DESCRIPTION OF THE DRAWINGS

FIG. 1A is a schematic side view of main portions of a lid opening/closing system according to an embodiment of the present invention and a pod placed in the lid opening/closing system;

FIG. 1B is a schematic sectional view, taken along the line 1B-1B, of the structure illustrated in FIG. 1A;

FIG. 1C is a schematic view of the structure of FIG. 1A as seen from the direction of the arrow 1C;

FIG. 1D is a schematic view of the structure of FIG. 1A as seen from the direction of the arrow 1D;

FIG. 1E is a partially perspective schematic top plan view of the portion indicated by the line 1E-1E of FIG. 1A;

FIG. 2 is a diagram, similar to FIG. 1, illustrating how structures as illustrated in FIG. 1A are stacked together in multiple stages in a vertical direction;

FIG. 3 is a diagram, similar to FIG. 1A, illustrating how, in the structure of FIG. 1A, a pod 2 is driven to cause a lid 4 to abut a door 15 to be thereby retained;

FIG. 4 is a diagram, similar to FIG. 1A, illustrating how, in the structure of FIG. 1A, the pod 2 temporarily retreats to cause the lid 4 to be separated from a pod main body 2a;

FIG. 5 is a diagram, similar to FIG. 1A, illustrating how, in the structure of FIG. 1A, the door 15 rotates to cause the lid 4 and the door 15 to be accommodated in an accommodation space 20c;

FIG. 6 is a diagram, similar to FIG. 1A, illustrating how, in the structure of FIG. 1A, the pod 2 moves to an insertion/extraction position for a wafer 1, enabling to execute inserting/extracting operation;

FIG. 7 is a diagram schematically illustrating a substrate processing apparatus according to an embodiment of the present invention; and

FIG. 8 is an enlarged view of a main portion of the structure of the present invention as illustrated in FIG. 7.

### DETAILED DESCRIPTION OF THE PREFERRED EMBODIMENTS

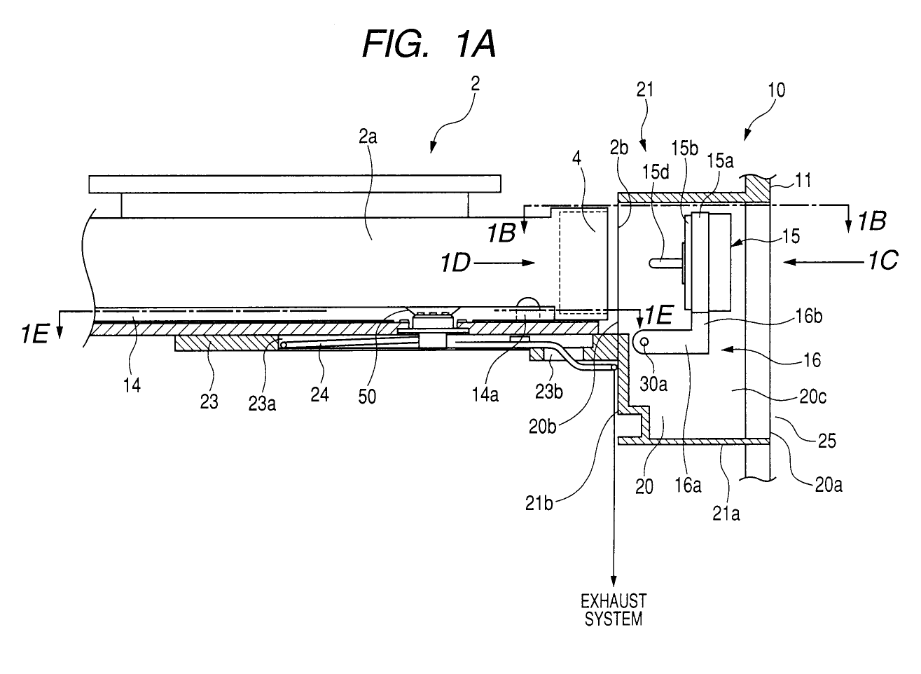

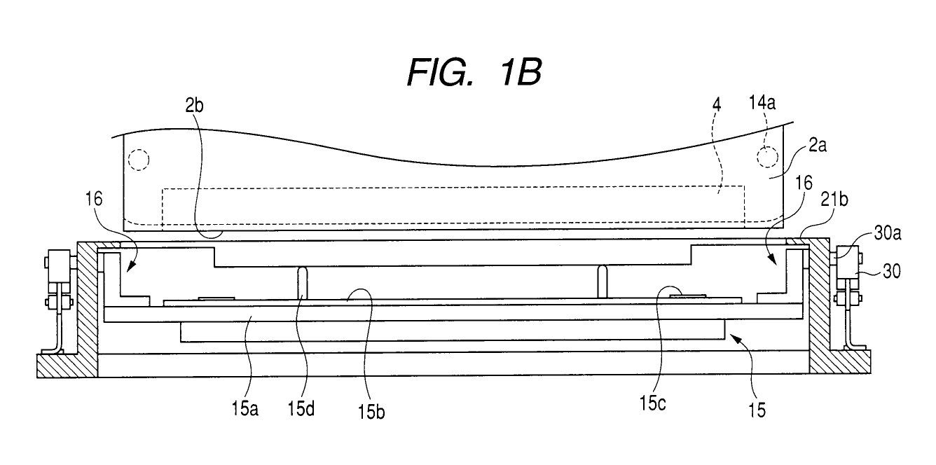

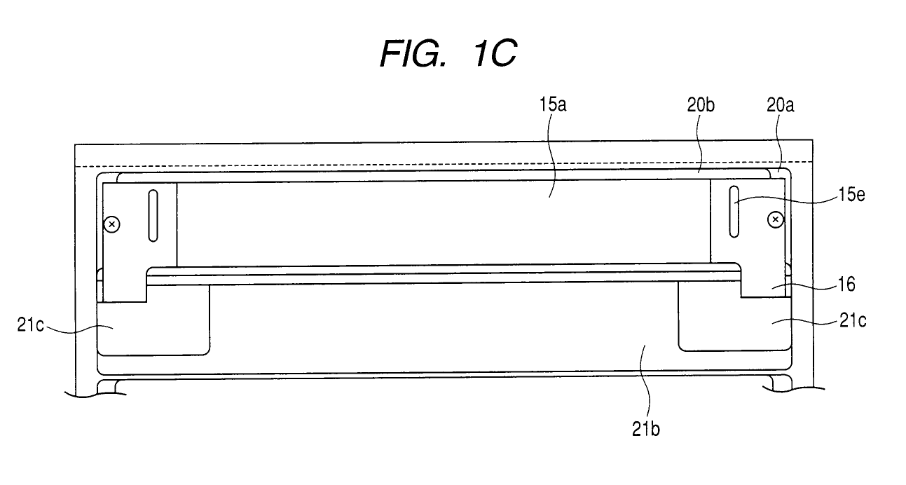

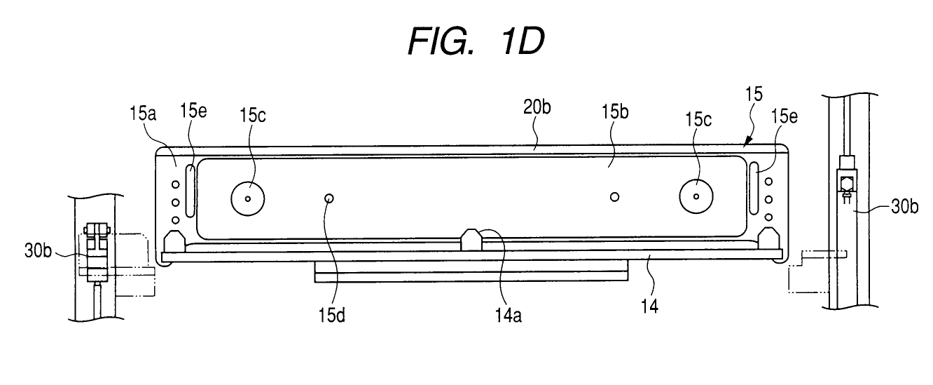

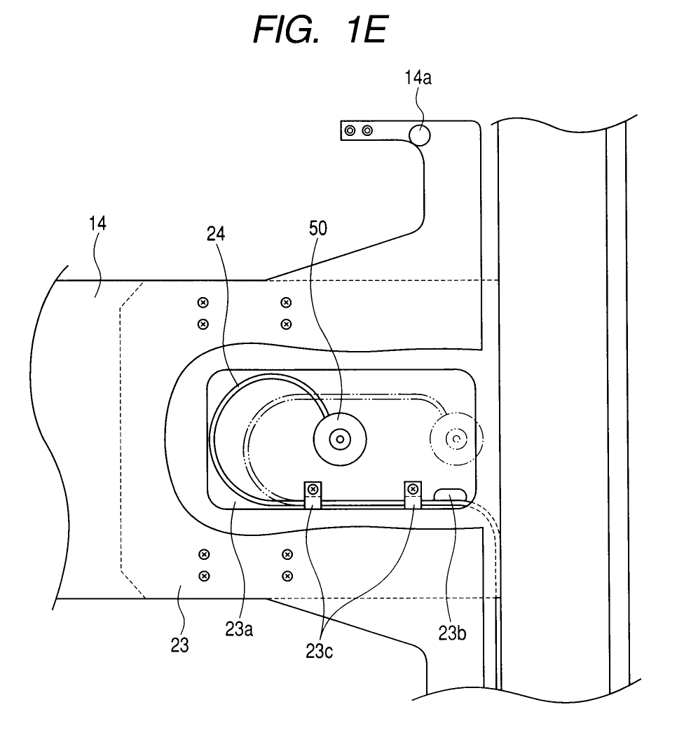

In the following, an embodiment of the present invention is described with reference to the drawings. FIG. 1A is a schematic side view of a part of a thin pod to which the present invention is to be applied and a lid opening/closing system that can deal with each pod individually. While actually multiple systems illustrated in FIG. 1A, etc. are stacked together, in the following, a single system is described for the sake of convenience. FIG. 1B is a sectional view, taken along the line 1B-1B of FIG. 1A, of the system illustrated in FIG. 1A, FIG. 1C is a side view of the same as seen from the direction of the arrow 1C (mini-environment side), and FIG. 1D is a side view of the same as seen from the direction of the arrow 1D (external space side), with the pod removed. FIG. 1E is a schematic structural view of only a movable plate, an attraction pad, and components related thereto seen from a direction of an arrow 1E (from above), in which the movable plate is illustrated as a partial perspective view.

Here, to be described first is a pod mounted on the lid opening/closing system and a wafer to be accommodated in the pod. Formed inside a pod main body 2a of the pod 2 is a space for accommodating one to several wafers to be processed. The pod main body 2a is formed in a thin, substantially box-like configuration having an opening in one of the surfaces existing in the horizontal direction. The pod 2 has a lid 4 for sealing the opening 2b of the pod main body 2a. Arranged inside the pod main body 2a is a shelf (not shown) having multiple stages for vertically stacking together wafers 1 that are retained horizontally, and the wafers 1 mounted thereon are accommodated inside the pod 2 at fixed intervals. The wafers 1 correspond to the objects to be accommodated in the present invention, the pod 2 corresponds to the container, the pod main body 2a, which has a basically box-like configuration, corresponds to the main body defined as a body of a substantially box-like configuration, and the opening 2b of the pod 2, which is basically of a rectangular configuration, corresponds to the opening defined as a substantially rectangular opening.

The lid opening/closing system 10 applied in this embodiment includes a mount base 13, a door 15, a tunnel member 21 constituting a tunnel 20, a door opening/closing mechanism 30, and a wall 11 which is a member forming the outer wall of a mini-environment 25 (conveyance chamber described below) communicating with the tunnel. The mount base 13 includes a movable plate 14 on which the pod 2 is actually mounted, which can move the mounted pod toward and away from a first opening 10, and which has a flat surface on its top. A positioning pin 14a is embedded in the flat surface of the movable plate 14, and the positioning pin 14a is fit-engaged with a positioning recess (not shown) provided in the lower surface of the pod main body 2a, whereby the positional relationship between the pod 2 and the movable plate 14 is uniquely determined. The movable plate 14 is connected to a well-known drive mechanism (not shown) including a stepping motor, a ball screw, etc., and in the state in which the pod 2 is mounted thereon, the plate can be stopped at four positions including a loading position for the pod 2 described below, a lid retaining position, a lid removing position, and a wafer insertion/extraction position. In the present invention, the structure including the mount base 13 or the movable plate 14 functions as a container support mechanism or a support mechanism which supports the pod or the like and moves the pod in a predetermined direction.

An attraction pad 50 is arranged on the upper surface of the movable plate 14. The attraction pad 50 protrudes upwardly from the surface of the movable plate 14 high enough to be capable of easily attracting and retaining the pod 2 when the attraction pad performs attracting operation, with the pod 2 being placed on the movable plate 14. The attraction pad 50 extends through the movable plate 14 such that the exhaust port side thereof reaches the back surface of the movable plate 14, and the exhaust port is connected to an exhaust system (not shown) via a vinyl tube 24. While in this embodiment a vinyl tube is used as the member forming the exhaust route since the vinyl tube is thin, flexible, and easy of handling, the vinyl tube is also possible to use various other materials as long as the materials are flexible enough and effective in suppressing dust. A box-like member 23 is arranged under the movable plate 14. The box-like member 23 is fixed to the wall 11, and has an upwardly open accommodation recess 23a. Further, there is provided in the bottom surface of the accommodation recess 23a and in the vicinity of the wall 11 a lead-out hole 23b leading the vinyl tune 24 outwardly from the accommodation recess 23a.

The vinyl tube 24 is fixed to the inner wall of the accommodation recess 23b by a fastening member 23c in the vicinity of the lead-out hole 23b. Thus, even when the movable plate 14 moves to the mini-environment side, the region extending from the box-like member 23 and the portion of the vinyl tube 24 fastened to the fastening member 23c to the exhaust system undergoes no change from the state in which the movable plate 14 is at the initial position. Further, the region extending from the portion of the vinyl tube 24 fastened to the fastening member 23c to the exhaust port of the attraction pad 50 is long enough not to affect the operation of the movable plate 14 so as to be capable of being deflected. In order that the vinyl tube 24 can be deflected independently of the operation of the movable plate 14, the accommodation recess 23a has a depth somewhat larger than the outer diameter of the vinyl tube 24 and a length and a width large enough to be capable of retaining the region fastened to the fastening member and the deflected region. In FIG. 1E, the solid line indicates the state of the vinyl tube 24 in the initial state in which the pod 2 is mounted on the movable plate 14, and the chain double-dashed line indicates the state of the vinyl tube 24 when the movable plate 14 is closest to the mini-environment 25 and when inserting/extracting operation for the wafers constituting the objects to be accommodated is possible.

When the movable plate 24 moves so as to pull the vinyl tube 24, there is usually a fear of generation of dust due to the movement of the vinyl tube 24 or due to contact of the vinyl tube 24 with a member such as the bottom surface of the movable plate 14. Further, depending upon the deflection of the vinyl tube 24, a state can easily occur in which the vinyl tube 24 itself is deflected downwardly. Such deflection as described above can be prevented to some degree through an increase in the number of fastening members 23c. However, the increase in the number of fastening members 23c leads to an increase in the number of members rubbed against the vinyl tube 24, thereby increasing the fear of dust generation. As in this embodiment, by adopting a construction in which the vinyl tube itself is confined within the box-like member 23 and in which the fastening member is arranged in the vicinity of the portion extending from the box-like member to the exterior so as to suppress the movement of the vinyl tube, it is possible to prevent downward drooping of the vinyl tube and, even in the case of generation of dust, to confine the generated dust within the box-like member 23, thereby maintaining the cleanliness of the ambient environment. From the viewpoint of the above-mentioned effect, the box-like member may have an accommodation space, that is, a recess, large enough to be capable of accommodating within a substantially closed space the deflected region due to the movement of the movable plate 14.

The tunnel member 21 includes a peripheral wall portion 21a which rises vertically from the wall 11 toward the external space, that is, in the driving direction of the movable plate 14 and which forms a space whose section perpendicular to the rising direction is rectangular, and an end wall portion 21b restricting the external space side opening of the peripheral wall portion 21a. The lateral length of the tunnel 20 formed by the tunnel member 21 (longitudinal length of the opposing surface of the pod 2 when the pod 2 is opposed to the tunnel 20, that is, the horizontal length) is set larger than the longitudinal length of the surface of the pod 2 opposed to the tunnel so that the pod 2 can be accommodated. The tunnel 20 has two openings: a mini-environment side opening 20a and an external space side opening 20b. That is, the tunnel 20 functions as a tunnel which is open in the vicinity of the space in which the pod 2 is mounted (i.e., loaded) on the movable plate 14 and which establishes communication between the external space and the mini-environment.

The external space side opening 20b has a lateral length corresponding to the lateral length of the above-mentioned tunnel 20 and a longitudinal length set slightly larger than the lateral length of the opposing surface of the pod 2. As a result, the pod 2 can enter the external space side opening 20b. The lateral length of the mini-environment side opening 20a is determined taking into consideration the width of an L-shaped arm 16 described below to be arranged so as not to interfere with the pod 2, in addition to the lateral length of the above-mentioned tunnel 20 allowing passage of the pod 2. Its longitudinal length is a length large enough to form an accommodation space 20c accommodating the door 15 retaining the lid 4 of the pod 2 and a part of the door opening/closing mechanism arranged inside the tunnel 20 plus a length slightly larger than the longitudinal length of the above-mentioned opposing surface of the pod 2.

The depth of the tunnel 20 (distance from the external space side opening 20b to the mini-environment side opening 20a) is set based on the relationship between the length of the both linear portions of the L-shaped arm 16 supporting the door 15 described below and the lateral length of the pod lid 4 or the lateral length of the door 15. More specifically, the depth is set such that the portion of the door 15 or the lid 4 closest to the mini-environment side when the door 15 exists at the retracted position (wafer insertion/extraction position) does not protrude into the mini-environment, and that the opening of the pod 2 at the position where the lid 4 is removed from the pod 2 (lid insertion/extraction position) can exist inside the tunnel 20. An end wall portion 21b restricts the opening to make the size of the external space side opening 20b the above-mentioned one, and its lateral length is determined from the relationship between the size of the opposing surface of the pod 2 and the mini-environment side opening 20a. The end wall portion 21b determines the above-mentioned space 20c.

The door 15 has a flat-plate-like abutment member 15b capable of opposing the lid 4 of the pod 2 and having an opposing surface substantially similar to the lid 4, and a door main body portion 15a retaining the abutment member 15b on a flat board surface and imparting strength to the abutment member. The door main body portion 15a has a longitudinal length smaller than the longitudinal length of the mini-environment side opening 20a, and eliminates a fear of occurrence of contact with the periphery of the opening at the time of rotation when opening/closing the lid 4. The abutment member 15b is arranged at the longitudinal center of the door main body portion 15a. Arranged on the surface of the abutment member 15b opposed to the pod 2 are an attraction pad 15c adapted to vacuum-attract the lid 4 to retain the same, a positioning pin 15d determining the positional relationship between the lid 4 and the abutment member 15b. The positioning pin 15d may also serve to retain the lid, in which case it also functions as a so-called latch key. At both sides of the abutment member 15b of the door main body portion 15a, there are formed slits 15e extending through the main body portion from the mini-environment side surface (back surface) to the external space side surface (front surface) and extending in the lateral direction of the door main body 15c. Further, one end portion (fixing end portion described below) of the L-shaped arm 16 of an L-shaped configuration is connected to both side portions of the abutment member 15b of the door main body portion 15a. The attraction pad 15c functions as a retaining mechanism for the wafer constituting the object to be accommodated together with an evacuation system (not shown) connected thereto and generating an attraction force in the pad.

The L-shaped arm 16 includes a rotation shaft side linear portion 16a connected to a door opening/closing mechanism 30 via a rotation shaft 30a described below at an end thereof, and a door side linear potion 16b connected to the door main body portion 15a at an end. The end portion of the door side liner portion 16b acts as a fixing end portion fixed to the door main body portion 15a, and the door side linear portion extends parallel to the extension surface of the door main body portion 15a. The rotation shaft 30a extends through the tunnel member 21 and is connected to a drive mechanism main body 30b of the door opening/closing mechanism 30 arranged outside the tunnel member. The drive mechanism main body 30b includes a well-known air cylinder, a link mechanism etc., and rotates the rotation shaft 30a between predetermined two angles. The rotation shaft 30a is set to be orthogonal to a predetermined direction which is the driving direction of the movable plate 14 and parallel to a surface perpendicular to the pod opening (extension surface of the wafer constituting the object to be accommodated).

Further, in this embodiment, the portion of the pod 2 in the vicinity of the opening 2b enters the interior of the tunnel 20. Tunnels 20 each similarly accommodating a pod 2 are arranged above and below the tunnel 20, and hence the tunnel 20 only has a size large enough to allow intrusion of the portion of the pod in the vicinity of the pod opening 2b and the portion of the movable plate 14 in the vicinity of the forward end thereof. Further, the movable plate 14 itself is set to have a very small thickness allowing securing of rigidity high enough not to cause deformation of the movable plate 14 with the pod 2 placed thereon and not to generate inclination or the like when allowing the pod 2 to enter the tunnel 20. Thus, the exhaust port of the attraction pad 50 cannot but be arranged so as to extend through the back surface of the movable plate 14. In this embodiment, it is necessary to set the arrangement of the attraction pad such that the exhaust port exits outside the tunnel 20 in the state in which the movable plate 14 has caused the pod 2 to advance to a depth with respect to the interior of the tunnel 20. In an example of the case in which the pod 2 placed on the movable plate 14 is inclined, the pod 2 may be caused to climb onto the information pad pins by information pads (not shown) arranged on both sides of the lid. In order to effectively suppress the inclination thus caused, it is desirable for the attraction pad 50 to be arranged at a position as near as possible to the opening of the pod 2. In many cases, the force inclining the pod 2 is applied from the pod opening side, and by arranging the attraction pad 50 on the opening side, it is possible to apply a force for fixing the pod 2 in position in the vicinity of the point of action of an unintended external force.

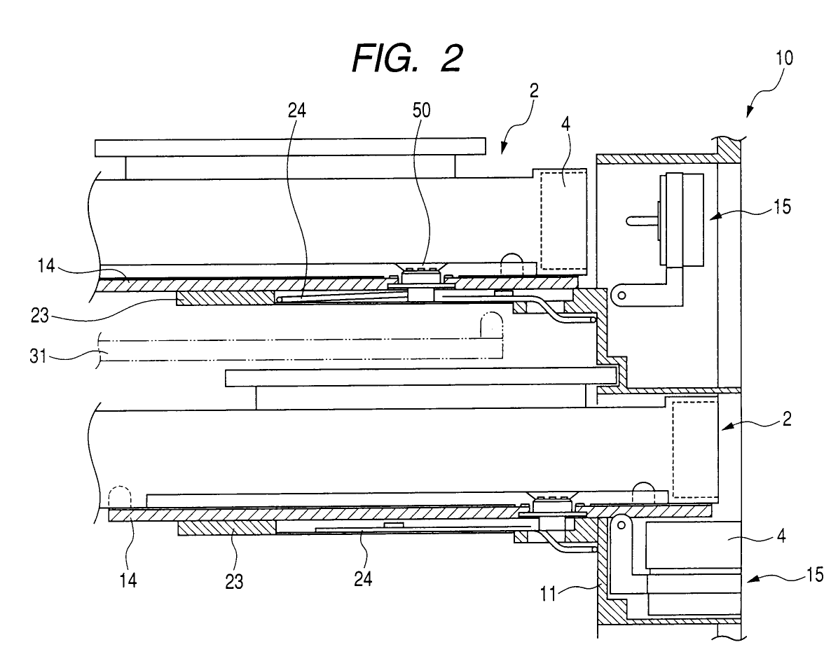

FIG. 2 illustrates in the same manner as FIG. 1A the state in which the above-mentioned main portions are stacked together in the vertical direction. The main portion on the upper stage is in the initial stage, in which the pod 2 is placed on the movable plate 14, and the main portion of the lower stage is in a state in which the pod 2 has been conveyed by the movable plate 14 to a position where insertion/extraction of the accommodated object is possible. Further, in this embodiment, by utilizing an upper flange 2c arranged in the upper portion of the pod 2 (see Japanese Patent Application Laid-Open No. 2000-286319), loading or unloading of the pod 2 onto or from the movable plate 14 is effected by using a delivery robot 31 indicated by the chain double-dashed line in FIG. 2. The operation space for the delivery robot is arranged in correspondence with a turnout space for the door 15, which must be provided between the upper and lower pods 2 vertically arranged. In this embodiment, downward deflection of the vinyl tube 24 is prevented by the box-like member 23, whereby the operation space for the delivery robot 31 can be secured easily and in a stable manner.

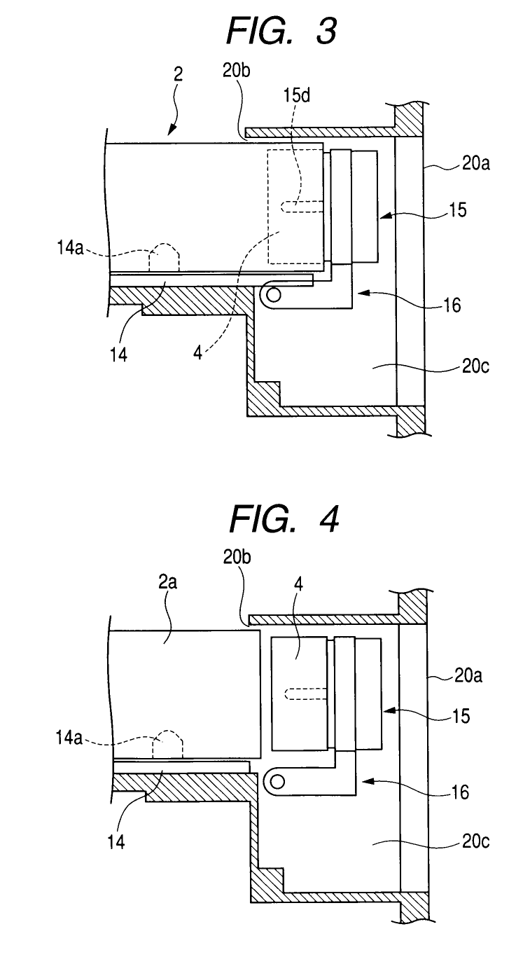

Next, the actual operation of the lid opening/closing mechanism, constructed as described above, is illustrated. First, as illustrated in FIGS. 1A through 1D, in the state in which the door 15 substantially closes the tunnel 20, the pod 2 is placed on the movable plate 14 existing at the loading position. At this stage, the attraction pad 50 is operated to attract and retain the lower surface of the pod 2. After the pod 2 has been placed at a predetermined position on the movable plate 14 by the action of a positioning pin 14a or the like, the movable plate 14 is caused to advance in the direction of the door 15 by a drive mechanism (not shown). The movement of the movable plate 14 by the drive mechanism is stopped at the position where the lid 4 for closing the pod 2 abuts the attraction pad 15c. In this process, a positioning pin 15d is fitted into a positioning recess (not shown) provided in the lid 4, and abutment of the lid 4 and the door 15 in an abnormal arrangement is prevented. After the abutment, the attraction pad 15c executes attraction and retention of the lid 4 by an exhaust mechanism (not shown). FIG. 3 illustrates this state. From this operation onward, the attraction pad 50 constantly attracts and retains the pod 2, and hence solely the components such as the door are depicted, and the operation of those components is described.

When the retention of the lid 4 is effected by the door 15 via the attraction pad 15c, the movable plate 14 retreats to a predetermined lid removal position with the pod 2 placed thereon. Through this retreating movement, the lid 4 retained by the door 15 is separated from the opening 2b of the pod 2. At the time of separation, the pod main body 2a may be attached to the lid 4 due to a seal member (not shown) or due to a difference in pressure between the interior of the pod 2 and the external space. Thus, it is desirable for the pod main body 2a to be fixed to the movable plate 14 by various constructions. In this embodiment, the lower surface of the pod 12 is attracted and retained by the attraction pad 50 so as to be fixed. However, in addition to this, the length of the positioning pin 14a may be set larger than a certain length to thereby provide a help to oppose the force applied to the pod main body 2a from the lid 4 at the time of retreat of the movable plate by the positioning pin 14a. In FIG. 4, the system is at the lid removal position where the movable plate 14 has retreated to a predetermined position, with the lid 4 being separated from the pod main body 2a.

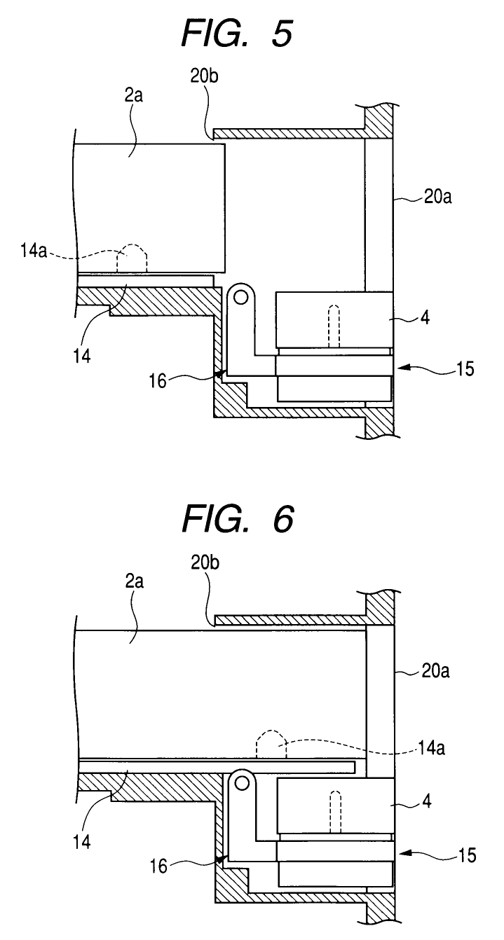

While the movable plate 14 maintains this rest state, the door 15 is rotated by the door opening/closing mechanism 30. The rotation of the door 15 is stopped at the condition illustrated in FIG. 5, and the door 15 and the lid 4 are accommodated in the accommodating space 21. Subsequently, the movable plate 14 advances, and as illustrated in FIG. 6 or lower main portion of FIG. 2, the movable plate 14 is stopped when the pod 2 reaches the wafer insertion/extraction position. In this state, the lid 4, the door 15, etc. are under the pod 2, with the movable plate 14 therebetween. Thus, synergistically with the effect of a down flow generated in the mini-environment 25, dust or the like adhering to the components such as the lid cannot easily enter the interior of the pod 2. Further, due to the generation of the down flow, the interior of the mini-environment is maintained at a pressure higher than that of the external space. Thus, inside the tunnel 20, there is constantly generated an airflow from the mini-environment side toward the external space side, and the risk of the dust or the like adhering to the lid 4, etc. heading for the opening 2b of the pod 2 is further reduced. Further, in this embodiment, from the viewpoint of attaining the above-mentioned effect, there is maintained an appropriate interval between the inner wall of the tunnel 20, the periphery of the door, and the outer periphery of the pod (interval generating an airflow through the gap without excessively reducing the difference in pressure between the interior of the mini-environment and the external space and without generating an excessive flow velocity).

Due to the provision of the lid opening/closing system constructed as described above, despite the fact that each of the intervals between the pods arranged in the vertical direction and the plates for supporting the same is very small, it is possible to fix and retain the pods by the plates reliably and easily. Further, an attraction force supplying tube deflectable in conformity with the movement of the plates and adapted to generate rubbing or the like is retained in a closed box-like space, whereby it is possible to prevent dust or the like generated from the tube from reaching the lower pods, and to secure in a stable manner the operation space for the pod delivery robot. Further, as in this embodiment, a so-called tunnel is arranged, whereby, when removing the pod lid from the pod main body, the lid and the mechanism for opening/closing the lid are arranged at positions avoiding the down flow, more specifically, at positions in the tunnel where there is formed no portion protruding toward the mini-environment. As a result, it is possible to insert and extract wafers or the like to and from the pod. Thus, there is no fear of dust or the like being blown away from the pod lid or the lid opening/closing mechanism by the down flow. Further, the other pods, lids, the drive mechanisms thereof, etc. are also arranged in individual tunnels, and hence it is also possible to reduce the fear of dust or the like due to one lid or the like re-adhering to components such as other lids.

In this embodiment, the present invention is basically applied to a lid opening/closing system having a so-called tunnel as proposed by the present applicant. However, the object of the application of the present invention is not restricted to this form. For example, it is also applicable to a system having no tunnel as disclosed in Japanese Patent Application Laid-Open No. 2000-286319. In this case, in order to supply an attraction force to an attraction pad serving as an attracting unit and the attraction pad, the vinyl tube, that is, the tube-like member for connecting the exhaust system and the attraction pad is arranged at a position where the tube-like member does not enter the mini-environment.

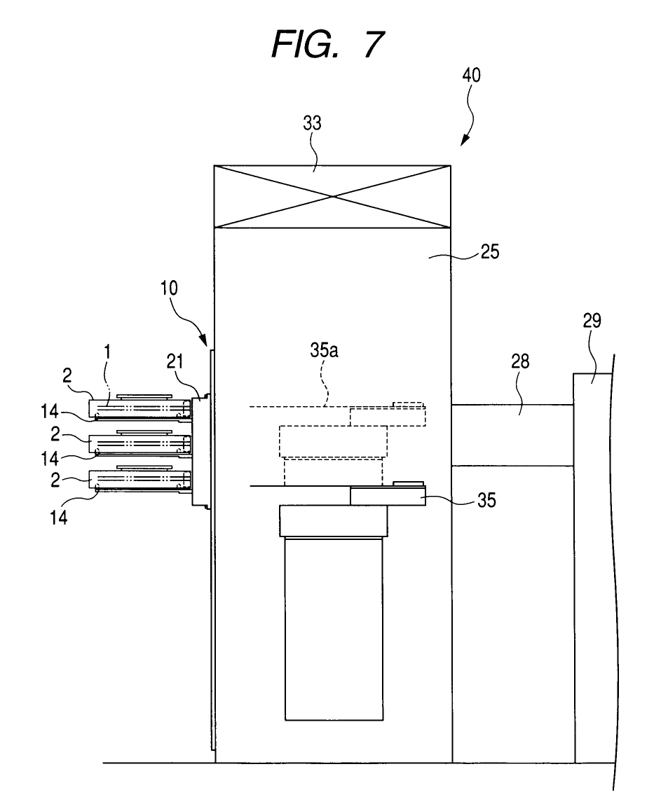

Next, as an embodiment of the present invention, a substrate processing apparatus actually using the above-mentioned lid opening/closing system is described. FIG. 7 is a side view schematically illustrating the construction of a semiconductor wafer processing apparatus (substrate processing apparatus) 40 adapted to the so-called mini-environment system. The semiconductor wafer processing apparatus 40 includes the load port portion (FIMS system, i.e., the lid opening/closing device) 10, the conveyance chamber (mini-environment) 25, and a processing chamber 29 as main components. The joint portions between those components are separated by a load port side wall 11 and a processing chamber side communication passage 28. In the conveyance chamber 25 of the semiconductor wafer processing apparatus 40, in order to discharge dust and maintain a high degree of cleanliness, an airflow (down flow) from the upper side to the lower side of the conveyance chamber 25 is generated by a fan filter unit 33 provided in the upper portion of the conveyance chamber. The lower surface of the conveyance chamber 25 is formed of a mesh or the like, whereby there is formed a discharge route for the down flow. Due to the above-mentioned construction, an air controlled in dust, etc. is always introduced into the conveyance chamber 25, and dust or the like existing in the conveyance chamber or brought in from the pod or the like is always carried downwards by the down flow, and discharged.

On the load port portion 10, pods 2 serving as storage containers for silicon wafers or the like (hereinafter simply referred to as wafers) are installed on mount bases 14. In the apparatus according to this embodiment, three pods are vertically arranged one upon the other, with each pod 2 containing two wafers 1. As described above, in order to process the wafers 1, a high degree of cleanliness is maintained inside the conveyance chamber 25. Further, inside the conveyance chamber, there is provided a conveyance robot 35 capable of actually retaining wafers as a conveyance mechanism. The conveyance robot 35 can move in the direction in which pods 2 are stacked together (in the vertical direction), and can rotate a robot arm 35a by 360 degrees coaxially. The wafers 1 are transferred between the interior of the pods 2 and the interior of the processing chamber 29 by the conveyance robot 35. The processing chamber 29 usually contains various mechanisms for performing processings such as thin film formation and thin film processing on the wafer surfaces, etc. However, such components are not directly related to the present invention, and hence a description thereof is omitted.

As described above, each pod 2 includes a space for accommodating two wafers 1 constituting the objects to be treated, a box-like pod main body 2a having an opening in one of the surfaces thereof, and a lid 4 for sealing the opening. Inside the pod main body 2a, there is arranged a shelf with multiple stages for stacking the wafers 1 together in one direction, and the wafers 1 placed therein are accommodated inside the pod 2 at a fixed interval. While in the example illustrated herein, the tunnel member 21 has multiple (three systems of) tunnels 20 inside thereof, the above-mentioned tunnel 20 is simply formed in correspondence with the arrangement of the movable plate 14, and regarding the details thereof, the tunnels 20 are the same as those of the form described above. That is, here, a description and a detailed depiction of the tunnel 20 are omitted since the main construction of the present invention has already been described with reference to the above embodiment and from the viewpoint of facilitating the understanding of the drawing.

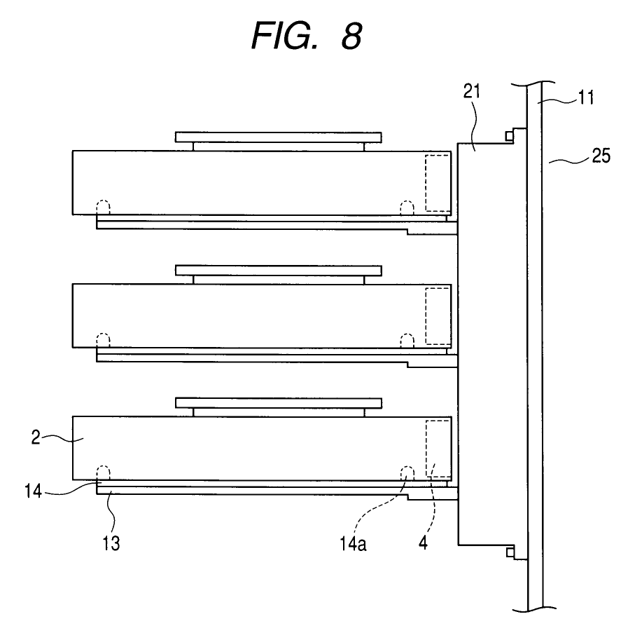

FIG. 8 is an enlarged view of the lid opening/closing system 10 of FIG. 7. In the conventional FIMS system adapted to a pod retaining a large number of wafers, the lid has to be of a size not smaller than a certain level, and hence the door which removes the lid and closes the opening of the mini-environment cannot but move within the mini-environment and stop within the space. In the present invention, the door is formed in a thin and narrow plate-like configuration, and hence relative movement is possible between pods in an amount corresponding to the lid width and the door, and the lid and the door are rotated to the exterior of the pod movement region, whereby it is possible to attain a state in which insertion/extraction of wafers into/from the pod is possible. Thus, as illustrated in FIG. 8, the door opening/closing mechanism can be arranged inside a tunnel independent of the mini-environment 25.

For example, when the robot is driven through combination of movements in three dimensions of X, Y, and Z, there may exist an obstacle in each dimension, making it necessary to move the robot while avoiding the obstacles. In such cases, in order to safely operate the robot, it is necessary to provide a considerably complicated safety circuit. In the present invention, there exists no component protruding into the mini-environment 25 and causing a problem in the drive in the vertical direction (Z-axis direction) of the robot. Thus, a safety circuit or the like is actually only necessary when the operation of inserting/extracting wafers is to be performed, and hence the circuit formation is substantially facilitated. Further, the mini-environment 25 contains no components other than the robot 35, and hence there exists no component disturbing the down flow, in particular, no component disturbing the down flow around the pod opening, whereby the discharge efficiency for dust or the like in the down flow is enhanced. Similarly, the possibility of generation of dust from the door or the like due to disturbance of the down flow is reduced. Further, according to the semiconductor equipment and materials international (SEMI) standards used in the semiconductor industry, arrangement of a protrusion around the opening for insertion/extraction of wafers on the mini-environment side inner wall of the wall forming the mini-environment is not allowed. In this respect, the present invention is in conformity with the standards.

According to the present invention, despite the fact that each of the intervals between the pods arranged in the vertical direction and the plates for supporting the same is very small, it is possible to fix and the retain the pods by the plates reliably and easily. Further, an attraction force supplying tube deflectable in conformity with the movement of the plate and adapted to generate rubbing or the like is retained in the box-like space, whereby it is possible to prevent dust or the like generated from the tube from reaching the lower pods, and to secure in a stable manner the operation space for the pod delivery robot.

While the above embodiments have been described as applied to FOUP and FIMS, the application of the present invention is not restricted thereto. The lid opening/closing device of the present invention can be applied to any system as long as it is one which uses a front open type container accommodating multiple objects to be retained and in which the insertion/extraction of the objects to be retained into/from the container is effected through opening/closing of the lid of the container.

As many apparently widely different embodiments of the present invention can be made without departing from the sprit and scope thereof, it is to be understood that the invention is not limited to the specific embodiment thereof except as defined in the appended claims.

This application claims priority from Japanese Patent Application No. 2007-308927 filed Nov. 29, 2007, which is hereby incorporated by reference herein.

What is claimed is:

1. A lid opening/closing system having a container provided with a substantially box-like main body capable of accommodating in an interior thereof an object to be accommodated and having an opening in one surface extending in a vertical direction and a lid separable from the main body and adapted to close the opening to form a sealed space together with the main body, the opening being opened by removing the lid from the container to thereby allow insertion/extraction of the object to be accommodated, the lid opening/closing system comprising:
a container support mechanism supporting the container and capable of moving the container in a predetermined direction;
a mini-environment separated from an external space except for an opening of a predetermined size, dust-controlled, and accommodating a mechanism conveying the object to be accommodated;
a door having a retaining mechanism abutting the lid and retaining the lid and adapted to rotate around a rotation shaft orthogonal to the predetermined direction and parallel to an extension surface of the object to be accommodated to thereby substantially close or establish communication between the interior of the container and the mini-environment; and
an attracting means arranged on an upper surface of the container support mechanism and capable of attracting and retaining a bottom surface of the container.

2. A lid opening/closing system according to claim 1, further comprising: a tunnel having an external space side opening that is an opening on the external space side in the vicinity of a position where the container is loaded in the container support mechanism, and a mini-environment side opening communicating with the mini-environment, opening on the mini-environment side, and matched with the opening of the predetermined size,
wherein the position where the attracting means attracts and retains the container is a position where the attracting means does not enter the tunnel even when the container support mechanism has conveyed the container to a position closest to the mini-environment.

3. A lid opening/closing system having a container provided with a substantially box-like main body capable of accommodating in an interior thereof an object to be accommodated and having an opening in one surface extending in a vertical direction and a lid separable from the main body and adapted to close the opening to form a sealed space together with the main body, the opening being opened by removing the lid from the container to thereby allow insertion/extraction of the object to be accommodated, the lid opening/closing system comprising:
a container support mechanism supporting the container and capable of moving the container in a predetermined direction;
a mini-environment separated from an external space, dust-controlled, and accommodating a mechanism conveying the object to be accommodated;
a tunnel having an external space side opening that is an opening on the external space side in the vicinity of a position where the container is loaded in the container support mechanism, and a mini-environment side opening communicating with the mini-environment and opening on the mini-environment side;
a door having a retaining mechanism abutting the lid and retaining the lid, being located with in the tunnel, being adapted to rotate around a rotation shaft orthogonal to the predetermined direction and parallel to an extension surface of the object to be accommodated, and being capable of canceling a state in which the tunnel is substantially closed; and
an attracting means arranged on an upper surface of the container support mechanism and capable of attracting and retaining a bottom surface of the container,
wherein the position where the attracting means attracts and retains the container is a position where the attracting means does not enter the tunnel even when the container support mechanism has conveyed the container to a position closest to the mini-environment.

4. A lid opening/closing system according to claim 3, wherein the attracting means has a suctional pad actually attracting and retaining the container and a tube-like member connecting the attraction pad to an exhaust system for supplying an attraction force to the attraction pad,
the lid opening/closing system further comprising: a box-like member for accommodating in a substantially closed space a region of the tube-like member that deflects as the container support mechanism operates.

5. A lid opening/closing system according to claim 4, wherein a member directly supporting the container in the container support mechanism is a flat-plate-like member, and wherein the box-like member is arranged on a back surface of the flat-plate-like member and fixed to the lid opening/closing system independently of the container support mechanism.

6. A method of processing an object to be accommodated which uses a container provided with a substantially box-like main body capable of accommodating an object to be accommodated in an interior thereof and having an opening in one surface extending in a vertical direction and a lid separable from the main body and adapted to close the opening to form a sealed space together with the main body, the opening being opened by removing the lid from the container to thereby allow insertion/extraction of the object to be accommodated, the object to be accommodated being inserted/extracted into/from the container, a predetermined processing being performed on the object to be accommodated outside the container, the method of processing an object to be accommodated using a lid opening/closing system including:
a mini-environment that is dust-controlled;
a conveyance mechanism for the object to be accommodated arranged inside the mini-environment;
a door substantially closing an opening provided in the mini-environment and capable of retaining the lid; and
a support mechanism supporting the container to drive the container in a predetermined direction and causing the door to retain the lid,
the method of processing an object to be accommodated comprising:
fixing the container with respect to the support mechanism, with the container being supported by the support mechanism;
driving the support mechanism to cause the lid to abut the door to thereby cause the door to retain the lid;
driving the support mechanism and the door relative to each other in the predetermined direction to separate the container and the lid from each other;
rotating the lid and the door around a shaft orthogonal to the predetermined direction and contained in an extension surface of the object to be accommodated to cause the lid and the door to retreat from the drive region of the container;
driving the container in the predetermined direction to arrange the container at an insertion/extraction position for the object to be accommodated,
wherein the operation accompanying the opening/driving of the lid of the container is executed in a tunnel communicating with the mini-environment, and
wherein the container is fixed in position by being attracted and retained by an attracting means provided in the support mechanism, with a position where the attracting means attracts and retains the container being situated outside the tunnel when the container is arranged at the insertion/extraction position for the object to be accommodated.
